(19) United States
(12) Patent Application Publication
(10) Pub. No.: US 2002/0056855 A1
(43) Pub. Date: May 16, 2002

(54) Chip carrier assembly

(76) Inventor: Robert Reiner, Neubiberg (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/012,850

(22) Filed: Oct. 30, 2001

Related U.S. Application Data
(63) Continuation of application No. PCT/EP00/03080, filed on Apr. 6, 2000.

(30) Foreign Application Priority Data
Apr. 30, 1999 (EP) 99 108 708.1

(51) Int. Cl. H01L 31/0336

(52) U.S. Cl. 257/200

(57) ABSTRACT

A chip carrier assembly having a semiconductor chip that is embedded in a recess of a thin substrate. The recess is covered, at least on one side of the substrate, by a covering pad. The edge regions of the covering pad are fastened on the substrate, and the semiconductor chip is fastened on the covering pad.

### CROSS-REFERENCE TO THE RELATED APPLICATION

This application is a continuation of copending International Application No. PCT/EP00/03080, filed Apr. 6, 2000, which designated the United States.

### BACKGROUND OF THE INVENTION

### Field of the Invention

The invention relates to a chip carrier assembly, in which a semiconductor chip is embedded in a thin substrate. Paper or thin plastic films are examples of possible substrates.

There are, for example, known chip carrier assemblies in which thin semiconductor chips are embedded in a paper during the papermaking process. However, assemblies of this type have several disadvantages. First, production of such an assembly is only possible at the premises of the manufacturer of the substrate, here the paper manufacturer. Second, once placed in such an assembly, the semiconductor is poorly protected against external influences.

To allow it to be embedded in paper or some other substrate, the semiconductor chip must be very thin. It is therefore very susceptible to breakage. Furthermore, the substrate surrounding the semiconductor chip offers inadequate protection against external effects, whether they are of a mechanical or chemical nature, temperature influences or electrical effects.

A further disadvantage is that it is difficult to exactly position the semiconductor chip in the substrate.

### SUMMARY OF THE INVENTION

It is accordingly an object of the invention to provide a chip carrier assembly which overcomes the above-mentioned disadvantages of the prior art apparatus of this general type. In particular, it is an object of the invention to provide a chip carrier assembly that can be simply produced independently of the place where the substrate is produced, and in which the semiconductor chip is protected as much as possible against adverse external influences, and moreover, is exactly positioned in the substrate in a predetermined position.

With the foregoing and other objects in view there is provided, in accordance with the invention, a chip carrier assembly that includes a thin substrate having a thickness and a recess completely extending through the thickness of the substrate. The substrate has two opposing sides and a fastening portion. The chip carrier assembly also includes: a semiconductor chip configured in the recess; and at least one covering pad having a surface with edge regions that face the semiconductor chip. The covering pad covers the semiconductor chip on one of the two sides of the substrate and covers the fastening portion of the substrate. The edge regions of the covering pad are fastened on the fastening portion of the substrate. The semiconductor chip is fastened to the covering pad, and the substrate is made from either paper or plastic film.

In other words, the recess is covered, at least on one of the sides of the substrate, by a covering pad. The edge regions of this covering pad are fastened on the substrate. The semiconductor chip arranged in the recess of the substrate is in turn fastened on the covering pad.

In accordance with an added feature of the invention, covering pads are fastened to the substrate on both sides of the semiconductor chip.

In accordance with an additional feature of the invention, an adhesive is used to fasten the covering pads and/or the semiconductor chip. It is particularly preferred if self-adhesive covering pads, which could also be referred to as adhesive patches, are used.

The arrangement of the semiconductor chip in the substrate provides the advantage that the semiconductor chip can be positioned very exactly, since the recess in the substrate can be produced with high accuracy. The recess is expediently only slightly larger than the base area of the semiconductor chip to be inserted, with the result that the latter is arranged in the desired position in the assembly after insertion.

A further advantage is that the semiconductor chip may be thicker than was the case with the semiconductor chips which were embedded in the paper substrate during the papermaking process. For example, it is possible to provide a chip with a thicker passivation, which protects the semiconductor chip better against external chemical or mechanical influences, since the recess in the substrate also offers space for a thicker chip.

In accordance with another feature of the invention, protection against mechanical or chemical influences can be improved by choosing suitable materials for the covering pads. They may be selected, for example, in such a way that the covering pads stiffen the region of the chip carrier assembly in which the chip is located and consequently protect the chip additionally from breakage. Furthermore, it is possible to produce the covering pads from a material which is as impermeable as possible. In this way, the influence of chemicals on the semiconductor chip can be significantly reduced; the diffusion of ions to the chip is prevented.

Materials which are suitable in principle for the covering pads are paper or plastic film. Particularly suited are those films which are used for the production of holograms on chip cards or other applications.

In principle, any material in which semiconductor chips were already previously embedded can be used as a substrate. Paper or thin plastic films may be mentioned by way of example.

In accordance with a further feature of the invention, the covering pad (or pads) is pressed into the substrate to obtain a particularly stiff and solid assembly and so that the thickness of the assembly is not increased too much by applying the covering pad (or pads). The covering pad (or pads) is expediently pressed into the substrate so far that the chip carrier assembly is given a substantially planar surface. The thickness of the semiconductor chip is in this case expediently less than the thickness of the substrate.

In particular, suitable semiconductor chips for the chip carrier assembly are those which permit contactless data transmission to a reading/writing device. Semiconductor chips of this type are known in principle. They usually have a coil on one of the chip surfaces (“coil on chip”).

For protection against electrical, electrostatic or electromagnetic influences, the at least one covering pad of the chip carrier assembly may be conductive. For example, it is possible to provide the covering pad with a conductive layer, in particular a metallic layer. The conductive layer may cover the entire surface of the covering pad. However, conductive layers are also to be understood hereinafter as meaning layers which take up only part of the surface area of the covering pad.

For example, the conductive layer on the covering pad may take the form of a coil which is inductively coupled to a coil on the semiconductor chip. Since the covering pad has a larger surface than the semiconductor chip, the coil may also be larger than the coil on the chip surface if it runs in the edge region of the covering pad. It is consequently possible with the aid of the coil on the covering pad to achieve the effect that the coil on the semiconductor chip lies in an intensified field.

On the other hand, it is possible to make the conductive layer on the covering pad take the form of a band which runs substantially completely around the semiconductor chip. In particular, the conductive layer may be provided in the form of an annular band which runs outside that region with which the covering band covers the semiconductor chip. In the case of an electrostatic discharge, the conductive band can lead the current around the chip and in this way prevent it from being destroyed. If the chip is working with inductive transmission, it may be expedient to provide the band with an interruption in the circumferential direction, rather than leading the conductive band continuously around the semiconductor chip.

Further protection against mechanical loads can be achieved by providing pores or through-openings in the substrate in the region around the recess in which the semiconductor chip is arranged. These pores or through-openings lead to a stiffening of the substrate in this region.

In accordance with a concomitant feature of the invention, the pores or through-openings are filled with an adhesive, since this provides additional stiffness. If a conductive adhesive is used as the adhesive, a conducting connection between opposite covering pads can be additionally achieved. This variant is particularly expedient if a conducting connection between conductive regions of opposite covering pads is established by the pores or through-openings filled with conductive adhesive. For example, electrically conductive bands which are present on two covering pads arranged on either side of the semiconductor chip can be brought into electrical contact with each other in the way described.

Other features which are considered as characteristic for the invention are set forth in the appended claims.

Although the invention is illustrated and described herein as embodied in a chip carrier assembly, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1 to 5 show cross sectional views of examples of chip carrier assemblies;

FIG. 6 schematically shows a plan view of the chip carrier assembly shown in FIG. 4; and

FIG. 7 shows a cross sectional view of the chip carrier assembly illustrated in FIG. 1 with cooperating coils.

### DESCRIPTION OF THE PREFERRED EMBODIMENT

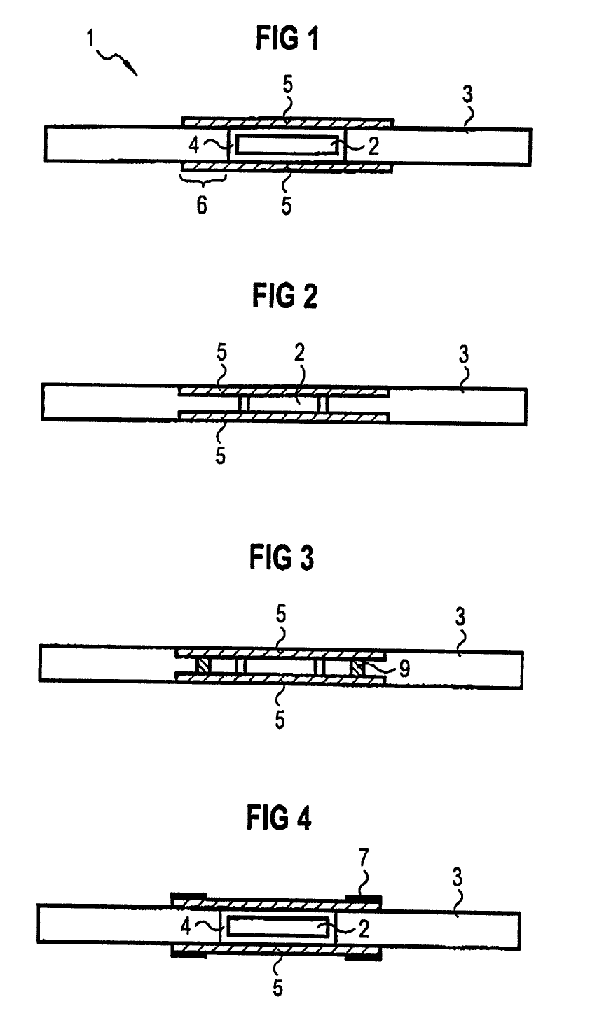

Referring now to the figures of the drawing in detail and first, particularly, to FIG. 1 thereof, there is shown a cross sectional view of a first example of a chip carrier assembly 1 taken through the region in which the semiconductor chip 2 is arranged. The semiconductor chip 2 is located in a recess 4, which has been punched into the substrate 3, here a thin paper.

The recess 4 is only slightly larger than the outer contour of the semiconductor chip 2. In this way, very exact positioning of the semiconductor chip in the substrate is possible. The semiconductor chip is fixed in the substrate using two covering pads 5. The covering pads 5 are adhesively fixed to the substrate 3 and to the upper side and underside of the semiconductor chip 2. The edge regions 6 of the covering pads 5 are connected to the substrate 3, and the central regions are connected to the semiconductor chip 2. In the case shown, the covering pads are self-adhesive, but the adhesive layer is not depicted. The lower covering pad 5 shown in FIG. 1 is expediently fastened to the substrate 3 before the semiconductor chip 2 is inserted into the recess 4. The upper covering pad 5 is expediently fastened after insertion of the semiconductor chip 2.

FIG. 2 shows a chip carrier assembly that substantially corresponds to that shown in FIG. 1. The same reference numerals used in FIG. 1 have been used to designate parts which are the same in this and all the of the subsequent figures. To avoid repetition, details already described will not be described again. As a difference from the assembly shown in FIG. 1, the covering pads 5 have been pressed into the substrate 3, with the result that the chip carrier assembly 1 has a substantially planar surface on the upper side and on the underside. Pressing in the covering pads can additionally increase the stiffness of the assembly and can even more securely fasten the semiconductor chip.

To increase the stiffness further, through-openings 9 can be arranged in the substrate 3 in the region around the recess 4, and this is illustrated in the chip carrier assembly shown in FIG. 3. These through-openings 9 are filled with adhesive, which is pressed into the through-openings 9 when the covering pads 5 are pressed together.

FIG. 4 shows a further example of a chip carrier assembly according to the invention, which once again largely corresponds to that shown in FIG. 1. However, a conductive band 7 is additionally arranged on the edge regions of each of the covering pads 5. In the chip carrier assembly as shown in FIG. 4, the conductive bands 7 in each case run on that side of the covering pads 5 which is facing away from the semiconductor chip 2.

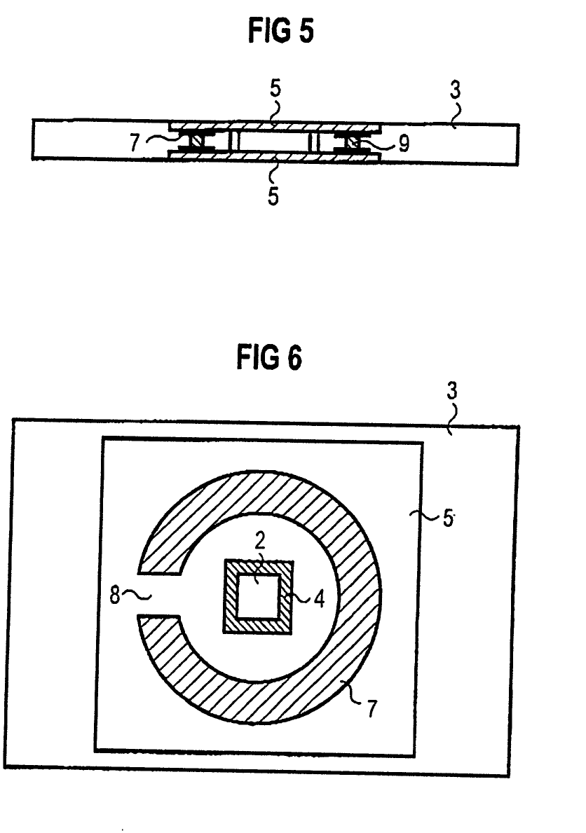

In the chip carrier assembly as shown in FIG. 5, however, the conductive bands 7 are in each case provided on that side of the covering pad 5 which is facing in the direction of the semiconductor chip 2. In both cases shown in FIGS. 4 and 5, the conductive band 7 is of an annular form, which can be seen from FIG. 6, which shows a plan view of the assembly as shown in FIG. 4. However, the bands 7 are not continuous but have an interruption 8 in the circumferential direction. In this way, the conductive rings 7 can be prevented from adversely influencing the inductive transmission between the semiconductor chip 2 and a reading/writing device. The conductive bands 7 prevent the semiconductor chip 2 from being destroyed by electrostatic discharge.

The embodiment shown in FIG. 5 has the further advantage that the annular conductive bands 7 of opposite covering pads 5 are in electrical contact with each other. This takes place using the through-openings 9 in the substrate 3, which are filled with an electrically conductive adhesive.

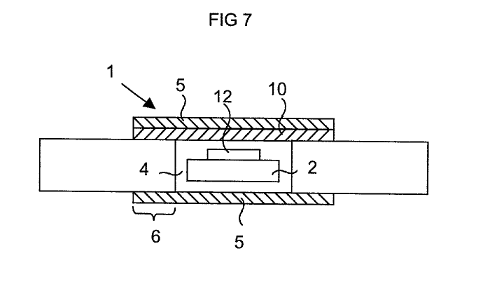

FIG. 7 shows a cross sectional view of the chip carrier assembly 1 illustrated in FIG. 1 in which the semiconductor chip 2 has a coil 12 that is inductively coupled with a coil 10 on the upper covering pad 5. The coils 10 and 12 have only been schematically illustrated for clarity.

We claim:

1. A chip carrier assembly, comprising:
a thin substrate having a thickness and a recess completely extending through said thickness of said substrate, said substrate having two opposing sides and a fastening portion;
a semiconductor chip configured in said recess; and
at least one covering pad having a surface with edge regions facing said semiconductor chip, said covering pad covering said semiconductor chip on one of said two sides of said substrate and covering said fastening portion of said substrate, said edge regions of said covering pad being fastened on said fastening portion of said substrate;
said semiconductor chip being fastened to said covering pad; and
said substrate being made from a material selected from the group consisting of paper and plastic film.

2. The chip carrier assembly according to claim 1, comprising an adhesive fastening said covering pad on said fastening portion of said substrate.

3. The chip carrier assembly according to claim 1, comprising an adhesive fastening said semiconductor chip to said covering pad.

4. The chip carrier assembly according to claim 1, wherein said covering pad is made of a material selected from the group consisting of paper and plastic film.

5. The chip carrier assembly according to claim 1, comprising:
a substantially planar surface defined by said substrate and said covering pad;
said covering pad being pressed into said substrate to obtain said planar surface.

6. The chip carrier assembly according to claim 1, wherein:
said semiconductor chip includes a coil; and
said covering pad includes a coil formed by an electrically conductive layer that is inductively coupled to said coil of said semiconductor chip.

7. The chip carrier assembly according to claim 6, wherein:
said covering pad includes a region that covers said semiconductor chip;
said conductive layer forms an annular band that runs outside said region of said covering pad;
said annular band defines an interruption; and
said annular band runs circumferentially completely around said semiconductor chip except for said interruption.

8. The chip carrier assembly according to claim 1, wherein said covering pad is provided with an electrically conductive layer for protecting against influences selected from the group consisting of electrical influences, electrostatic influences, and electromagnetic influences.

9. The chip carrier assembly according to claim 1, comprising:
a first covering pad defined by said at least one covering pad; and
a second covering pad having a surface with edge regions facing said semiconductor chip;
said substrate having a second fastening portion;
said second covering pad covering said semiconductor chip on another one of said two sides of said substrate and covering said second fastening portion of said substrate;
said edge regions of said second covering pad being fastened on said second fastening portion of said substrate; and
said semiconductor chip being fastened to said second covering pad.

10. The chip carrier assembly according to claim 9, wherein said substrate has adhesive-filled through-openings located around said recess and between said first covering pad and said second covering pad.

11. The chip carrier assembly according to claim 10, wherein:
said first covering pad has a first electrically conductive layer;
said second covering pad has a second electrically conductive layer; and
said adhesive is electrically conductive and establishes a conducting connection between said first electrically conductive layer and said second electrically conductive layer.

12. The chip carrier assembly according to claim 9, wherein said substrate has adhesive-filled pores located around said recess and between said first covering pad and said second covering pad.

13. The chip carrier assembly according to claim 12, wherein:
said first covering pad has a first electrically conductive layer;
said second covering pad has a second electrically conductive layer; and
said adhesive is electrically conductive and establishes a conducting connection between said first electrically conductive layer and said second electrically conductive layer.
